(19) United States
(12) Patent Application Publication
(10) Pub. No.: US 2026/0231724 A1
(43) Pub. Date: Aug. 6, 2026

(54) TRANSFER UNIT

(71) Applicant: SEMES CO., LTD., Chungcheongnam-do (KR)

(72) Inventors: Hyun Jun KIM, Pyeongtaek-si (KR); Jun Ho YOU, Cheonan-si (KR)

(21) Appl. No.: 19/343,016

(22) Filed: Sep. 29, 2025

(30) Foreign Application Priority Data
Sep. 30, 2024 (KR) 10-2024-0132409

(51) Int. Cl. H10P 72/00; H10P 72/30; H10P 72/76

(52) U.S. Cl. CPC H10P 72/0608; H10P 72/3202; H10P 72/7602

(57) ABSTRACT

Provided is a transfer unit, including: a hand on which a substrate is placed; and a detector for detecting whether the substrate supported on the hand protrudes from a regular position on the hand, in which the detector includes: a light-emitting sensor for emitting light; a body in which a light-receiving sensor that receives light emitted from the light-emitting sensor is installed on a bottom surface thereof; and a light blocking wall installed in the body and preventing light other than the light emitted by the light-emitting sensor from being introduced into the light-receiving sensor.

This application claims priority to and the benefit of Korean Patent Application No. 10-2024-0132409 filed in the Korean Intellectual Property Office on September 30, 2024, the entire contents of which are incorporated herein by reference.

### TECHNICAL FIELD

The present invention relates to a transfer unit that transfers a substrate, and more particularly, to a transfer unit that is capable of detecting whether a substrate protrudes.

### BACKGROUND ART

To manufacture a semiconductor device or liquid crystal display, various processes, such as photolithography, etching, ashing, ion implantation, thin film deposition, and cleaning, are performed on a substrate. Among them, the photolithography process includes an application process of applying a photoresist on the substrate, an exposure process of transferring a pattern to the photoresist on the substrate, and a development process of removing the selected region from the exposed substrate. The devices provided to perform these processes includes a transfer unit that transfers the substrate between chambers performing different processes.

In general, the transfer unit includes a hand on which the substrate is placed.

The transfer unit is driven at a high speed when a hand loads a substrate into the chamber, unloads a substrate out of the chamber, or when a transfer robot moves between the chambers. This causes the substrate to slide forward from the regular position on the hand. When the hand continues to move while the substrate is out of the regular position on the hand, the substrate falls off from the hand and is damaged.

To prevent this, the transfer robot includes a detector that detects whether the substrate protrudes forward from the regular position on the hand.

FIG. 1 is a diagram schematically illustrating a traveling direction of light according to a general transfer unit.

In general, the detector 1100 includes a light-emitting sensor 1110 and a light-receiving sensor 1120, and the light-emitting sensor 1110 and the light-receiving sensor 1120 are disposed in a body 1130 of a detector 1100.

The detector 1100 is positioned in front of a substrate W placed at a regular position on a hand (not illustrated). When the substrate W protrudes forward than the regular position on the hand, light emitted from the light-emitting sensor 1110 is reflected on the substrate W, and the light-receiving sensor 1120 receives the reflected light. That is, when the light-receiving sensor 1120 receives light, it is determined that the substrate W protrudes from the regular position on the hand.

However, various lights exist in the path through which the transfer robot is moved. For example, light emitted from an illumination for assisting in camera photographing may exist.

In general, since the substrate is made of a material that reflects light, the substrate may receive external light, such as light of the illumination. In this case, even though the substrate is placed in the regular position on the hand, it may be incorrectly determined that the substrate protrudes from the hand.

### SUMMARY OF THE INVENTION

The present invention has been made in an effort to provide a device capable of improving detection accuracy when detecting whether a substrate protrudes using a light-emitting sensor and a light-receiving sensor.

The present invention has also been made in an effort to provide a transfer unit that prevents a substrate from being determined to protrude by external light even in a state where the substrate does not protrude when the substrate is placed on a hand of the transfer unit.

The objectives of the present disclosure are not limited thereto and other objectives not stated herein may be clearly understood by those skilled in the art from the following description.

An exemplary embodiment of the present disclosure, a transfer unit for transferring a substrate, the transfer unit comprising: a hand on which a substrate is placed; and a detector for detecting whether the substrate supported on the hand protrudes from a regular position on the hand, wherein the detector includes: a light-emitting sensor for emitting light; a body in which a light-receiving sensor that receives light emitted from the light-emitting sensor is installed on a bottom surface thereof; and a light blocking wall installed in the body and preventing light other than the light emitted by the light-emitting sensor from being introduced into the light-receiving sensor.

An exemplary embodiment of the present disclosure, a transfer unit for transferring a substrate, the transfer unit comprising: a hand on which a substrate is placed; and a detector for detecting whether the substrate supported on the hand protrudes from a regular position on the hand, wherein the detector includes: a light-emitting sensor for emitting light; and a body in which a light-receiving sensor that receives light emitted from the light-emitting sensor is installed, a groove is formed on a bottom portion of the body, and the light-receiving sensor is disposed in the groove.

An exemplary embodiment of the present disclosure, a transfer unit for transferring a substrate, the transfer unit may comprising, a base plate; a hand which is installed on the base plate so as to be movable forwardly and backwardly on the base plate, and on which the substrate is placed; and a detector for detecting whether the substrate supported on the hand protrudes from a regular position on the hand, wherein the detector includes: a light-emitting sensor for emitting light; a body in which a light-receiving sensor that receives light emitted from the light-emitting sensor is installed on a bottom surface thereof; and a light blocking wall that is provided to protrude in a lower direction from the body at a position between the substrate placed in the regular position on the hand and the light-receiving sensor to prevent light other than the light emitted from the light-receiving sensor from being introduced into the light-receiving sensor.

According to the exemplary embodiment of the present invention, it is possible to improve detection accuracy when detecting whether a substrate protrudes using a light-emitting sensor and a light-receiving sensor.

Further, according to the exemplary embodiment of the present invention, it is possible to prevent a substrate from being determined to protrude by external light even in a state where the substrate does not protrude when the substrate is placed on a hand of the transfer unit.

Effects of the present disclosure are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a diagram schematically illustrating a traveling direction of light according to a general transfer unit.

FIG. 2 is a perspective view schematically illustrating a substrate processing apparatus according to an exemplary embodiment of the present invention.

FIG. 3 is a cross-sectional view of the substrate processing apparatus illustrating an applying block or a developing block of FIG. 2.

FIG. 4 is a top plan view of the substrate processing apparatus of FIG. 2.

FIG. 5 is a plan view schematically illustrating one example of a heat processing chamber of FIG. 4.

FIG. 6 is a front view of the heat processing chamber of FIG. 5.

FIG. 7 is a diagram schematically illustrating an example of a transfer unit.

FIG. 8 is a diagram schematically illustrating an example of a hand of the transfer unit of FIG. 7.

FIG. 9 is a cross-sectional view schematically illustrating a first exemplary embodiment of a detector of the transfer unit of FIG. 8.

FIG. 10 is a diagram illustrating a light-receiving state of a light-receiving sensor when a substrate is in a regular position on the hand in the detector according to the transfer unit of FIG. 9.

FIG. 11 is a diagram schematically illustrating a second exemplary embodiment of the detector of the transfer unit.

FIG. 12 is a diagram illustrating a light-receiving state of a light-receiving sensor when a substrate is in a regular position on the hand in the detector according to the transfer unit of FIG. 11.

FIG. 13 is a diagram schematically illustrating a third exemplary embodiment of the detector of the transfer unit.

FIG. 14 is a diagram illustrating a light-receiving state of a light-receiving sensor when a substrate is in a regular position on the hand in the detector according to the transfer unit of FIG. 13.

FIGS. 15 to 19 are diagrams schematically illustrating modified examples of the transfer unit, respectively.

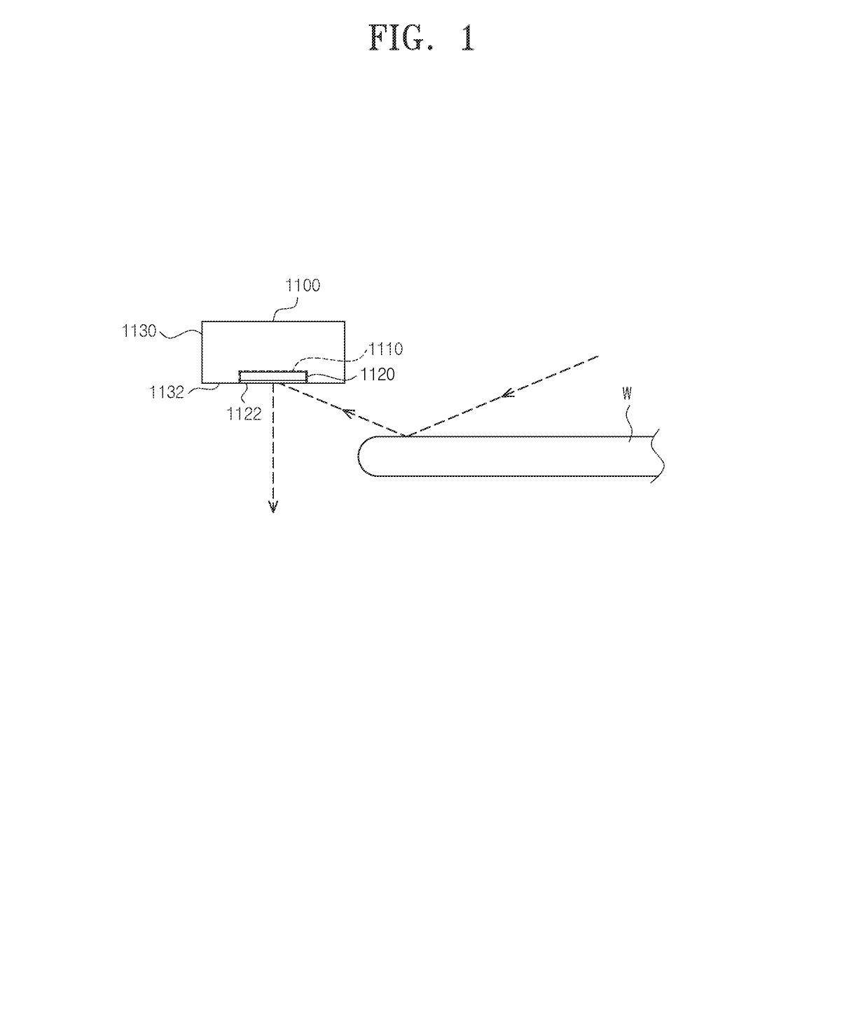

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms "including" and "having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Embodiments of the present disclosure may be modified in various ways and the scope of the present disclosure should not be construed as being limited to the embodiments to be described below. Embodiments are provided to more completely explain the present disclosure to those skilled in the art. Accordingly, the shapes of the components shown in the figures are exaggerated to enhance clearer description.

The system in the present exemplary embodiment is described as being used to perform photolithography processes on substrates, such as semiconductor wafers or flat panel displays, but this is for convenience of description, and the present invention may also be used in other devices including robots that transfer substrates to process substrates.

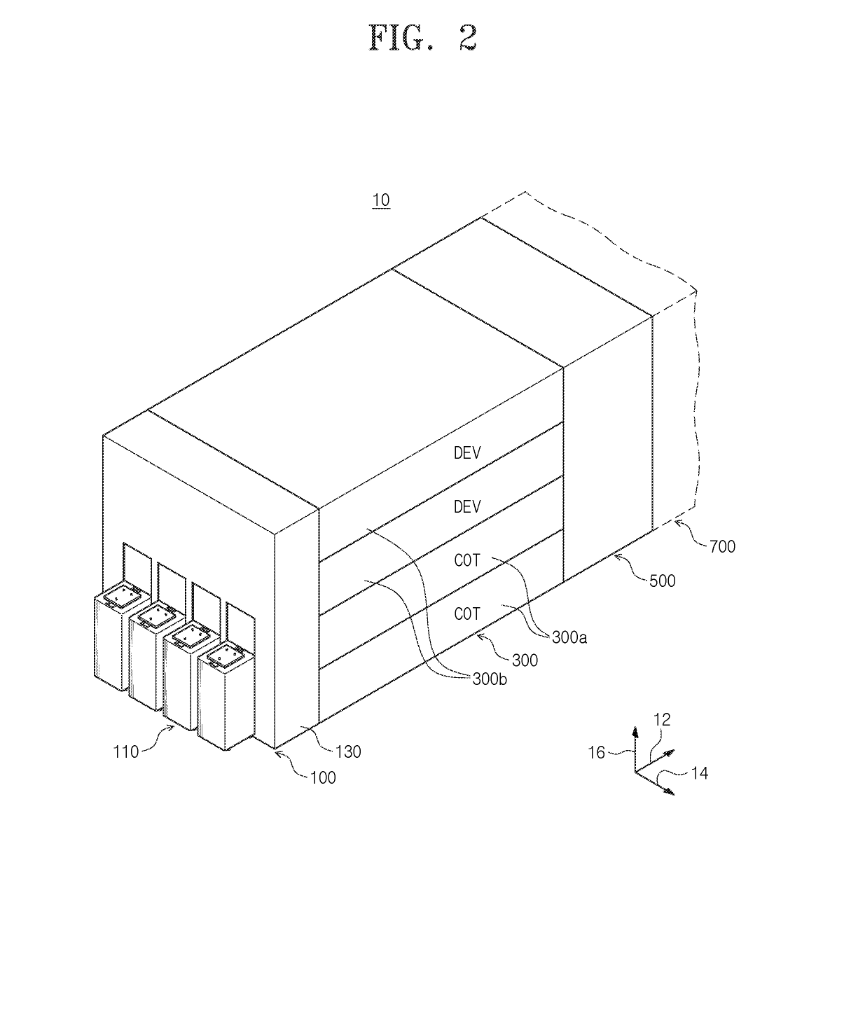

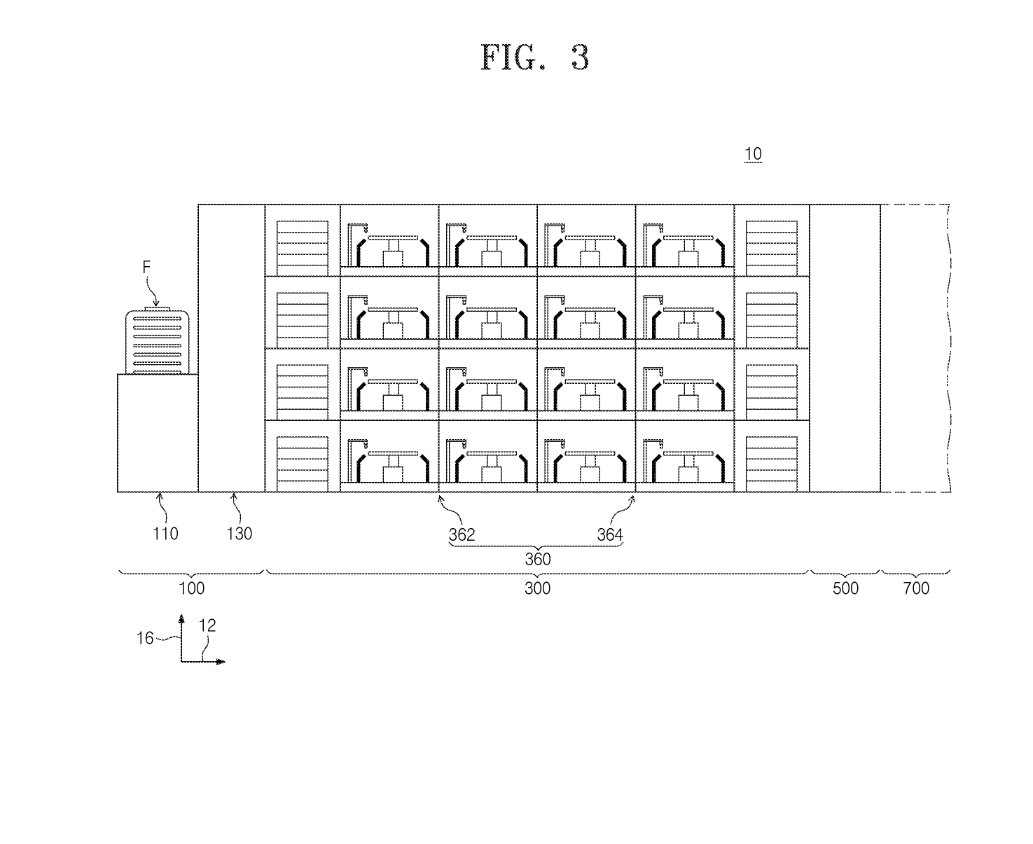

FIG. 2 is a perspective view schematically illustrating a substrate processing apparatus according to an exemplary embodiment of the present invention, FIG. 3 is a cross-sectional view of the substrate processing apparatus illustrating an applying block or a developing block of FIG. 2, and FIG. 4 is a top plan view of the substrate processing apparatus of FIG. 2.

Referring to FIGS. 2 to 4, a substrate processing apparatus 10 according to an exemplary embodiment of the present invention includes an index module 100, a processing module 300, and an interface module 500.

According to the exemplary embodiment, the index module 100, the processing module 300, and the interface module 500 are sequentially arranged in a line. Hereinafter, a direction in which the index module 100 and the processing module 300 are disposed is referred to as a first direction 12, and when viewed from above, a direction vertical to the first direction 12 is referred to as a second direction 14, and a direction perpendicular to both the first direction 12 and the second direction 14 is referred to as a third direction 16.

The index module 100 transfers a substrate W from a container F in which the substrate W is accommodated to the processing module 300, and makes the substrate W, which has been completely processed, be accommodated in the container F. A longitudinal direction of the index module 100 is provided in the second direction 14. The index module 100 includes a load port 110 and an index frame 130. Based on the index frame 130, the load port 110 is located at a side opposite to the processing module 300. The containers F in which the substrates W are accommodated are placed on the load ports 110. The load ports 110 may be provided in plurality, and the plurality of load ports 110 may be disposed in the second direction 14.

As the container F, an airtight container, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided to the index frame 130. A guide rail 136 of which a longitudinal direction is the second direction 14 is provided within the index frame 130, and the index robot 132 may be provided to be movable on the guide rail 136. The index robot 132 includes a hand on which the substrate W is placed, and the hand may be provided to be movable forward and backward, rotatable about the third direction 16, and movable along the third direction 16.

The processing module 300 may perform an application process and a development process on the substrate W. The processing module 300 may perform a substrate processing process by receiving the substrate W accommodated in the container F. The processing module 300 includes an applying block 300a, a developing block 300b, and a front buffer chamber 310.

The applying block 300a performs an application process on the substrate W, and the developing block 300b performs a developing process on the substrate W. A plurality of applying blocks 300a is provided, and they are provided to be stacked on each other. A plurality of developing blocks 300b is provided, and they are provided to be stacked on each other. According to the exemplary embodiment of FIG. 2, two applying blocks 300a and two developing blocks 300b are provided. The applying blocks 300a may be disposed under the developing blocks 300b. According to an example, the two applying blocks 300a perform the same process and may be provided in the same structure. Further, the two developing blocks 300b perform the same process and may be provided in the same structure.

Referring to FIG. 4, the applying block 300a includes a heat processing chamber 320, a transfer chamber 350, and a liquid processing chamber 360.

The heat processing chamber 320 performs a heat processing process on the substrate W. The heat processing process may include a cooling process and a heating process. The liquid processing chamber 360 forms a liquid film by supplying a liquid onto the substrate W. The liquid film may be a photoresist film or an antireflection film. The transfer chamber 350 transfers the substrate W between the heat processing chamber 320 and the liquid processing chamber 360 within the applying block 300a.

The transfer chamber 350 may be provided so that a longitudinal direction is parallel to the first direction 12. A transfer robot 900 is provided to the transfer chamber 350. The transfer robot 900 transfers the substrate between the heat processing chamber 320, the liquid processing chamber 360, and the buffer chambers 312 and 316. According to an example, the transfer robot 900 includes a hand on which the substrate W is placed, and the hand may be provided to be movable forward and backward, rotatable about the third direction 16, and movable along the third direction 16.

The front buffer chamber 310 may include a buffer transfer unit 2000, a plurality of buffer modules 312, and an adhesion baking module 315.

Some of the buffer modules 312 may include a cool plate where a substrate waits before being introduced into the applying block 300a after an adhesion baking processing.

An adhesion baking module 315 for hydrophobizing the surface of the substrate with hydrophobic gas before the applying process may be positioned at one side of the buffer transfer unit 2000. Herein, the hydrophobic gas may be hexamethyldisilane (HMDS).

The buffer transfer unit 2000 is disposed on one side of the buffer module 312. The buffer transfer unit 1000 may include a buffer loading robot that transfers a substrate before process processing to the applying module for the applying process, and a buffer unloading robot that moves the substrate W to the buffer module 312 located at a third or fourth stage so that the index robot 132 is capable of withdrawing the substrate after the process processing.

Referring back to FIGS. 2 to 4, a plurality of heat processing chambers 320 is provided. The heat processing chambers 320 are disposed along the first direction 12. The heat processing chambers 320 are located on one side of the transfer chamber 350.

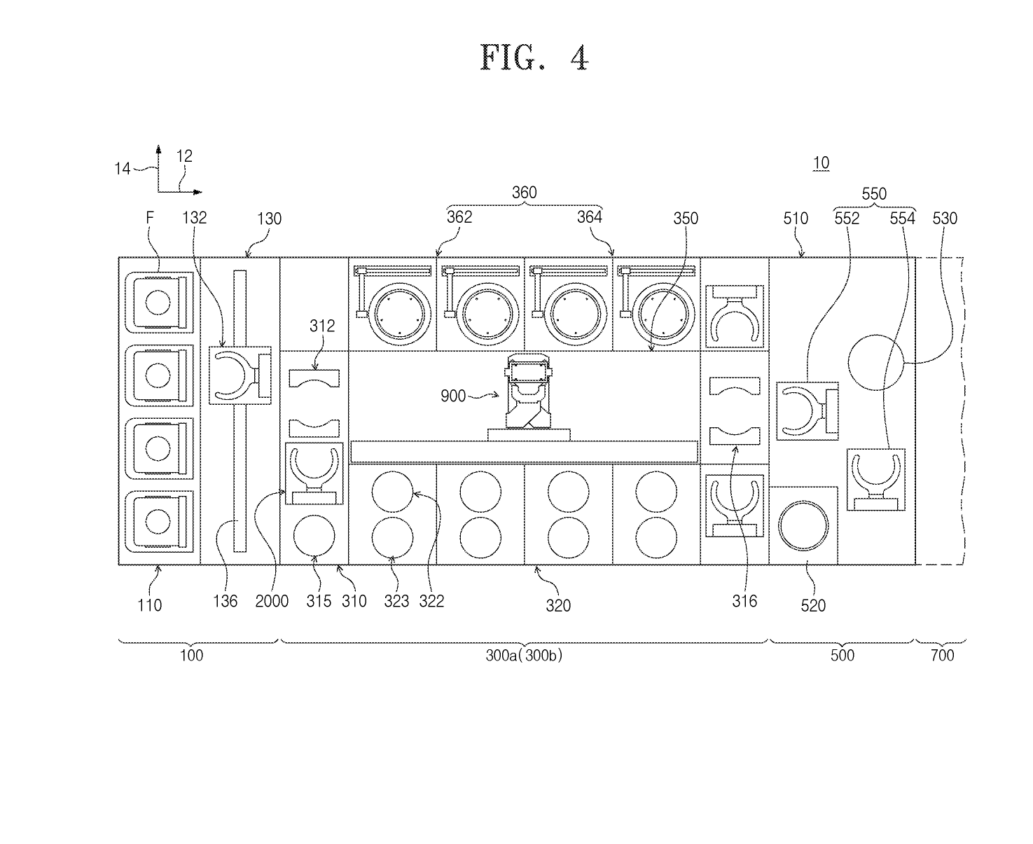

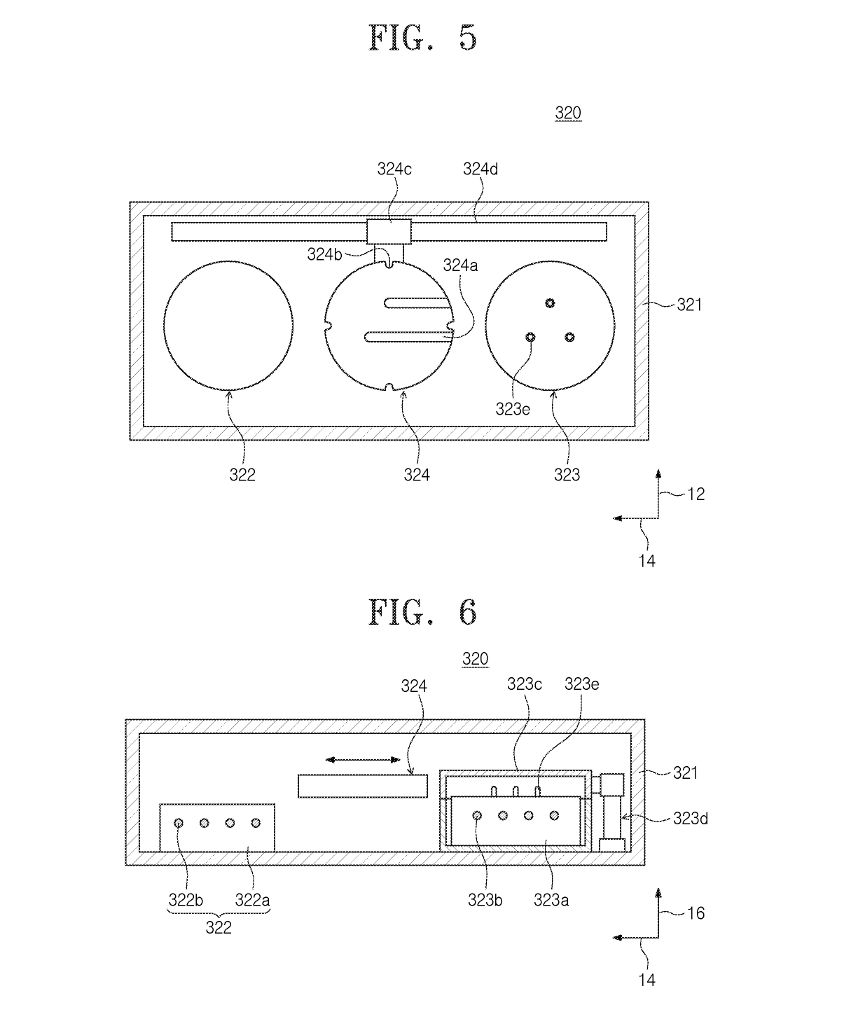

FIG. 5 is a plan view schematically illustrating one example of a heat processing chamber of FIG. 4, and FIG. 6 is a front view of the heat processing chamber of FIG. 5.

Referring to FIGS. 5 and 6, the heat processing chamber 320 includes a housing 321, a cooling unit 322, a heating unit 323, and a transfer plate 324.

The housing 321 is provided in a generally rectangular parallelepiped shape. An entrance opening (not illustrated) through which the substrate W enters and exits is formed on a sidewall of the housing 321. The entrance opening may remain open. A door (not illustrated) may be provided to selectively open and close the entrance opening. The cooling unit 322, the heating unit 323, and the transfer plate 324 are provided within the housing 321. The cooling unit 322 and the heating unit 323 are arranged along the second direction 14. According to an example, the cooling unit 322 may be positioned closer to the transfer chamber 350 than the heating unit 323.

The cooling unit 322 has a cooling plate 322a. When viewed from above, the cooling plate 322a may have a substantially circular shape. A cooling member 322b is provided on the cooling plate 322a. According to an example, the cooling member 322b is formed inside the cooling plate 322a and may be provided as a flow path through which a cooling fluid flows.

The heating unit 323 includes a heating plate 323a, a cover 323c, and a heater 323b. When viewed from above, the heating plate 323a has a generally circular shape. The heating plate 323a has a larger diameter than the substrate W. The heater 323b is installed on the heating plate 323a. The heater 323b may be provided as a heating resistor to which a current is applied. The heating plate 323a is provided with lift pins 323e that may be driven in the vertical direction along the third direction 16. The lift pin 323e receives the substrate W from a transfer means outside the heating unit 323 and puts the received substrate W down on the heating plate 323a, or lifts the substrate W from the heating plate 323a and transfers the substrate W to the transfer means outside the heating unit 323. According to an example, three lift pins 323e may be provided.

The cover 323c has an internal space in which a lower portion is open. The cover 323c is positioned above the heating plate 323a and is moved in the vertical direction by a driver 3236d. A space formed by the cover 323c and the heating plate 323a by moving the cover 323c is provided as a heating space for heating the substrate W.

The transfer plate 324 is generally provided with a disk shape and has a diameter corresponding to that of the substrate W. A notch 324b is formed at an edge of the transfer plate 324. The notch 324b may have a shape corresponding to that of a protrusion 3044 formed in a hand 3040 of the transfer robot 352 described above. Also, the notch 324b is provided by the number corresponding to that of the protrusions 3044 formed in the hand 3040, and is formed at a position corresponding to that of the protrusion 3044. When the vertical positions of the hand 354 and the transfer plate 324 are changed at a position where the hand 354 and the transfer plate 324 are vertically aligned, the substrate W is transferred between the hand 354 and the transfer plate 324. The transfer plate 324 may be mounted on the guide rail 324d and may be moved between a first region 3212 and a second region 3214 along the guide rail 324d by a driver 324c. A plurality of slit-shaped guide grooves 324a is provided in the transfer plate 324. The guide groove 324a extends from the end of the transfer plate 324 to the inside of the transfer plate 324. The guide groove 324a is provided so that a longitudinal direction thereof is the second direction 14, and the guide grooves 324a are spaced apart from each other along the first direction 12. The guide groove 324a prevents the transfer plate 324 and the lift pin 323e from interfering with each other when the substrate W is taken over between the transfer plate 324 and the heating unit 323.

Cooling of the substrate W is performed in a state in which the transfer plate 324 on which the substrate W is placed is in contact with the cooling plate 322a. The transfer plate 324 is made of a material having high thermal conductivity so that heat transfer between the cooling plate 322a and the substrate W is well performed. According to an example, the transfer plate 324 may be made of a metal material.

Referring back to FIGS. 2 to 4, a plurality of liquid processing chambers 360 is provided. Some of the liquid processing chambers 360 may be provided to be stacked on each other. The liquid processing chambers 360 are disposed on one side of the transfer chamber 350. The liquid processing chambers 360 are arranged side by side along the first direction 12. Some of the liquid processing chambers 360 are provided at positions adjacent to the index module 100. Hereinafter, the liquid processing chamber 360 positioned adjacent to the index module 100 is referred to as a front liquid processing chamber 362. Another part of the liquid processing chambers 360 is provided at a position adjacent to the interface module 500. Hereinafter, the liquid processing chamber 360 positioned adjacent to the interface module 500 is referred to as a rear liquid processing chamber 364.

The front liquid processing chamber 362 applies a first liquid on the substrate W, and the rear liquid processing chamber 364 applies a second liquid on the substrate W. The first liquid and the second liquid may be different types of liquids. According to the example, the first liquid is an antireflection film, and the second liquid is a photoresist. The photoresist may be applied on the substrate W to which the antireflection film is applied. Optionally, the first liquid may be a photoresist, and the second liquid may be an antireflection film. In this case, the antireflection film may be applied on the substrate W to which the photoresist is applied. Optionally, the first liquid and the second liquid are the same type of liquid, and all of them may be photoresist.

The developing block 300b has the same structure as the applying block 300a, and the liquid processing chamber provided to the developing block 300b supplies a developer onto the substrate.

The interface module 500 connects the processing module 300 to an external exposure device 700. The interface module 500 includes an interface frame 510, an additional process chamber 520, an interface buffer 530, and an interface robot 550.

A fan filter unit that forms descending airflow therein may be provided at an upper end of the interface frame 510. The additional process chamber 520, the interface buffer 530, and the interface robot 550 are disposed within the interface frame 510. The additional process chamber 520 may perform a predetermined additional process before the substrate W on which the process has been completed in the applying block 300a is loaded into the exposure device 700. Optionally, the additional process chamber 520 may perform a predetermined additional process before the substrate W on which the process has been completed in the exposure device 700 is loaded into the developing block 300b. According to an example, the additional process may be an edge exposure process for exposing an edge region of the substrate W, an upper surface cleaning process for cleaning the upper surface of the substrate W, or a lower surface cleaning process for cleaning the lower surface of the substrate W. A plurality of additional process chambers 520 may be provided, and they may be provided to be stacked on each other. All of the additional process chambers 520 may be provided to perform the same process. Optionally, some of the additional process chambers 520 may be provided to perform different processes.

The interface buffer 530 provides a space in which the substrate W transferred between the applying block 300a, the additional process chamber 520, the exposure device 700, and the developing block 300b temporarily remains during transfer. A plurality of interface buffers 530 may be provided, and a plurality of interface buffers 530 may be provided to be stacked on each other.

According to an example, the additional process chamber 520 may be disposed on one side and the interface buffer 530 may be disposed on the other side based on an extension line of the transfer chamber 350 in the longitudinal direction.

The interface robot 550 transfers the substrate W between the applying block 300a, the additional process chamber 520, the exposure device 700, and the developing block 300b. The interface robot 550 may have a transfer hand that transfers the substrate W. The interface robot 550 may be provided as one or a plurality of robots. According to an example, the interface robot 550 has a first robot 552 and a second robot 554. The first robot 552 may be provided to transfer the substrate W between the applying block 300a, the additional process chamber 520, and the interface buffer 530, and the second robot 554 may be provided to transfer the substrate W between the interface buffer 530 and the exposure device 700, and the second robot 554 may be provided to transfer the substrate W between the interface buffer 530 and the developing block 300b.

Each of the first robot 552 and the second robot 554 includes a transfer hand on which the substrate W is placed, and the hand may be provided to move forward and backward, rotate based on an axis parallel to the third direction 16, and move along the third direction 16.

Hereinafter, the transfer unit for transferring a substrate will be described in detail.

Hereinafter, the present invention will be described based on the case where the transfer unit is the transfer robot provided in the transfer chamber as an example. However, unlike this, the transfer unit may be an index robot or an interface robot. Optionally, the transfer unit may be a buffer transfer robot.

FIG. 7 is a diagram schematically illustrating an example of a transfer unit.

Referring to FIG. 7, a transfer unit 3000 includes a base plate 3020, a hand 3040, and a detector 3060. The base plate 3020 is generally provided in a rectangular parallelepiped cylindrical shape. The base plate 3020 is provided to be movable in the first direction 12 and the third direction 16 by a driving means (not illustrated).

The hand 3040 is installed on the base plate 3020 to be movable forward and backward with respect to the base plate 3020.

A hand driver (not illustrated) for moving the hand 3040 forward and backward is installed inside the base plate 3020. The hand driver moves the hand 3040 between a forward position and a backward position on the base plate 3020.

A guide groove 3022 is formed on a side surface of the base plate 3020. A hand support 3024 is inserted into the guide groove 3022. The guide groove 3022 is formed in a slit shape along a longitudinal direction of the base plate 3020.

The hand support 3024 is disposed through the guide groove 3022. The hand support 3024 may be provided in a bar shape. One end of the hand support 3024 is coupled to a driver (not illustrated), and the other end of the hand support 3024 is coupled to the hand 3040.

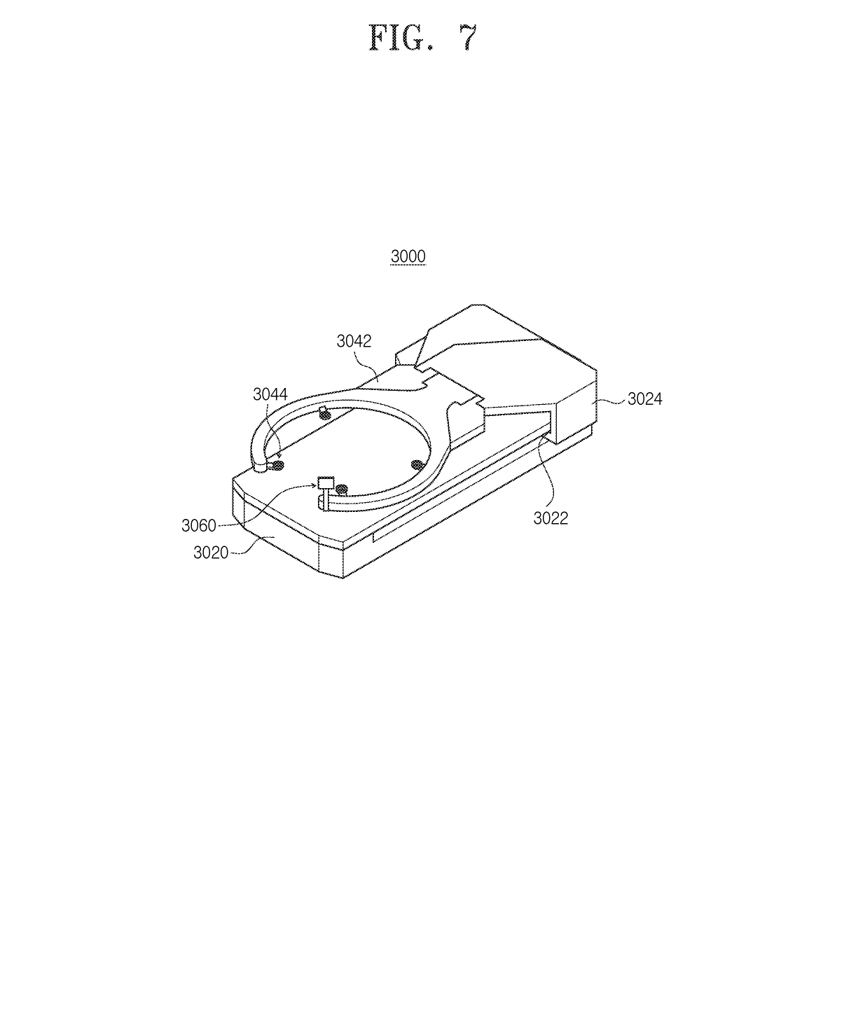

FIG. 8 is a diagram schematically illustrating an example of the hand of the transfer unit of FIG. 7.

Referring to FIG. 8, the hand 3040 supports a substrate. The hand 3040 includes a hand body 3042 and a supporting protrusion 3044. The hand body 3042 has a ring shape in which a portion of a circumference is bent. The supporting protrusion 3044 is provided on the hand body 3042. The supporting protrusion 3044 extends from an inner surface of the hand body 3042 toward a center of the hand body 3042. A plurality of supporting protrusions 3044 is provided. For example, four supporting protrusions 3044 may be provided at equal intervals. The substrate W is supported by the supporting protrusion 3044 in the hand 3040.

In a state in which the substrate W is placed on the hand 3040, the substrate W is placed in a regular position on the hand 3040. However, often during the movement of the hand 3040, the substrate W is moved out of the regular position on the hand 3040 moves in front of the hand 3040, and protrudes forward from the hand 3040. In this case, the substrate W may be separated from the hand 3040 and may be damaged. The detector 3060 detects whether the substrate W placed on the hand 3040 protrudes from the regular position on the hand 3040.

According to an example, the detector 3060 is installed in the hand 3040. A support for supporting the detector 3060 is installed in the hand 3040. The support is installed at the tip end of the hand 3040. The detector 3060 is coupled to the support. The detector 3060 is positioned higher than the substrate W placed in the regular position of the hand 3040.

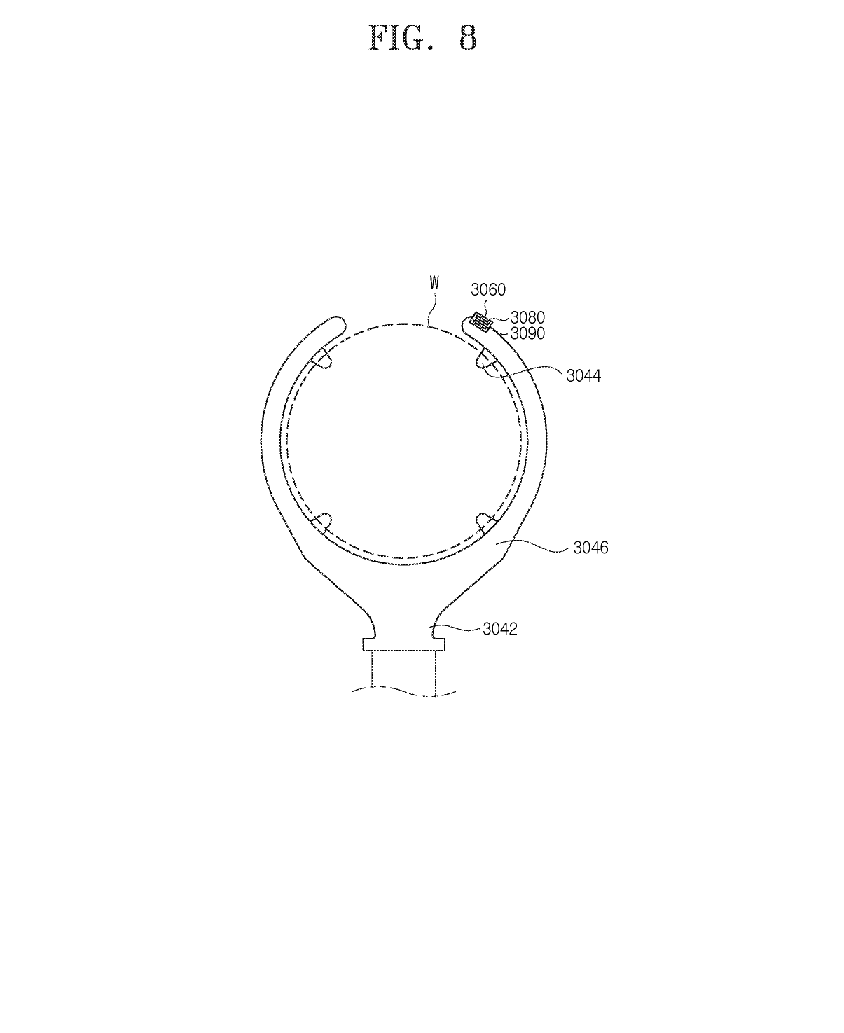

FIG. 9 is a cross-sectional view schematically illustrating a first exemplary embodiment of a detector of the transfer unit of FIG. 8.

Referring to FIG. 9, the detector 3060 includes a body 3070, a light-emitting sensor 3080, a light-receiving sensor 3090, and a light blocking wall 4000. In the body 3070, a light-emitting sensor 3080 and a light-receiving sensor 3090 are installed. The light-emitting sensor 3080 emits light in a downward direction. For example, the light may be laser light. The light-emitting sensor 3080 has a light-emitting surface 3082 which is a surface that emits light. The light-emitting surface 3082 may be provided in parallel to the substrate W placed in the regular position on the hand 3040. The light-receiving sensor 3090 receives light emitted from the light-emitting sensor 3080. When the substrate W is positioned to protrude from the hand 3040, light emitted from the light-emitting sensor 3080 is reflected from the substrate W, and the light-receiving sensor 3090 receives light reflected from the substrate. The light-receiving sensor 3090 has a light-receiving surface 3092 which is a surface that receives light. The light-receiving surface 3092 is provided on a bottom surface portion 3072 of the body 3070.

When the detector 3060 does not receive light, it is determined that the substrate W does not protrude and placed in the regular position on the hand 3040. Conversely, when the detector 3060 receives light, it is determined that the substrate W protrudes from the regular position on the hand 3040.

The light blocking wall 4000 blocks light other than light emitted from the light-emitting sensor 3080 from being introduced into the light-receiving sensor 3090. In general, various lights may be provided in the space in which the transfer unit 3000 is provided. For example, when a camera is installed to photograph a transfer space or a specific item in the transfer space, the light may be light emitted from an illumination. In addition, various types of light may be introduced into the transfer space from the outside of the transfer space in addition to the transfer space.

In this case, the light obliquely incident on the substrate W placed on the hand 3040 may be reflected from the substrate W and may be directed toward the light-receiving sensor 3090. The light blocking wall 4000 blocks the light reflected from the substrate W from being introduced into the light-receiving sensor 3090.

The light blocking wall 4000 is provided to protrude downward from the body 3070. According to the exemplary embodiment, the light blocking wall 4000 extends to protrude from the bottom surface 3072 of the body 3070. The light blocking wall 4000 is positioned between the substrate W and the light-receiving sensor 3090 in the regular position on the hand 3040. The light blocking wall 4000 is provided at a height capable of blocking light reflected from the substrate W. In addition, the light blocking wall 4000 does not interfere with a path of light emitted from the light-emitting sensor 3080, or a path of light emitted from the light-emitting sensor 3080 and received into the light-receiving sensor 3090.

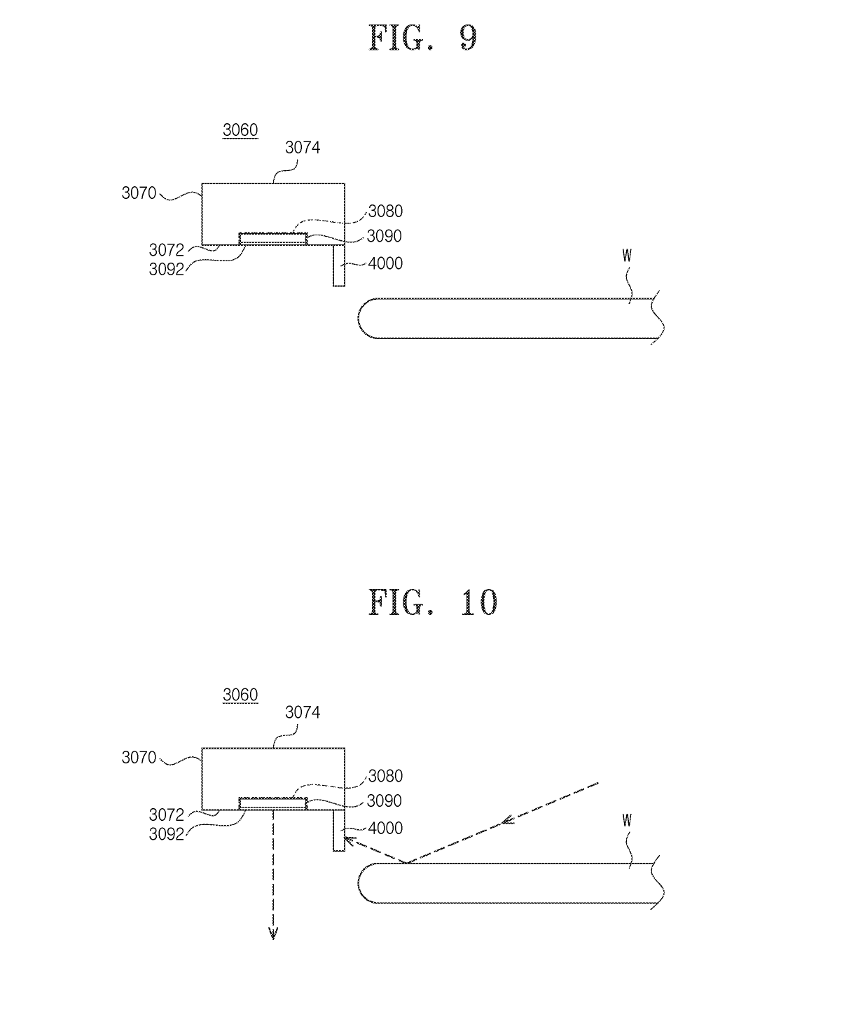

FIG. 10 is a diagram illustrating a light-receiving state of the light-receiving sensor when a substrate is in the regular position on the hand in the detector according to the transfer unit of FIG. 9.

First, when the light blocking wall 4000 is not provided, light emitted from a component, such as an illumination of a transfer space or a part of light introduced into the transfer space is obliquely incident on the substrate W placed on the hand 3040. In this case, light reflected from the substrate W may be directed to the light-receiving sensor 3090. In this case, even though the substrate W is in the regular position on the hand 3040, the light-receiving sensor 3090 receives the light reflected from the substrate W, and thus it may be wrongly determined that the substrate W protrudes from the regular position on the hand 3040.

Referring to FIG. 10, when the light blocking wall 4000 is provided, the light obliquely incident on the substrate W placed on the hand 3040 is reflected from the substrate W and directed toward the light-receiving sensor 3090. However, since the light blocking wall 4000 is provided between the light-receiving sensor 3090 and the substrate W, the light reflected from the substrate W does not reach the light-receiving sensor 3090.

FIG. 11 is a diagram schematically illustrating a second exemplary embodiment of the detector of the transfer unit. Hereinafter, a difference from the transfer unit according to the first exemplary embodiment of FIG. 9 will be mainly described.

Referring to FIG. 11, a transfer unit 3000 includes a base plate 3020, a hand 3040, and a detector 4060. In the transfer unit 3000 according to the exemplary embodiment of FIG. 11, the base plate 3020 and the hand 3040 are provided to be the same as or similar to the base plate 3020 and the hand 3040 of the transfer unit 3000 according to the exemplary embodiment of FIG. 9.

The detector 4060 includes a body 4070, a light-emitting sensor 4080, and a light-receiving sensor 4090. The body 4070 has a groove 4076 formed in the bottom portion 4072. The groove is formed by an inner side wall 4076a and an inner upper wall 4076b.

The inner side wall 4076a is provided perpendicular to the bottom portion 4072 of the body 4070. The inner upper wall 4076b is provided parallel to the bottom portion 4072 of the body 4070.

A light-emitting sensor 4080 and a light-receiving sensor 4090 are installed in the body 4070. The light-receiving sensor 4090 is inserted into the groove 4076 formed in the body 4070. In addition, the light-emitting sensor 4080 may be inserted into the groove 4076 formed in the body 4070. The light-receiving sensor 4090 is fixedly installed on the inner upper wall 4076b. That is, the light-receiving sensor 4090 is fixedly installed such that a light-receiving surface 4092 that is a surface that receives light is higher than the bottom surface 4072 of the body 4070.

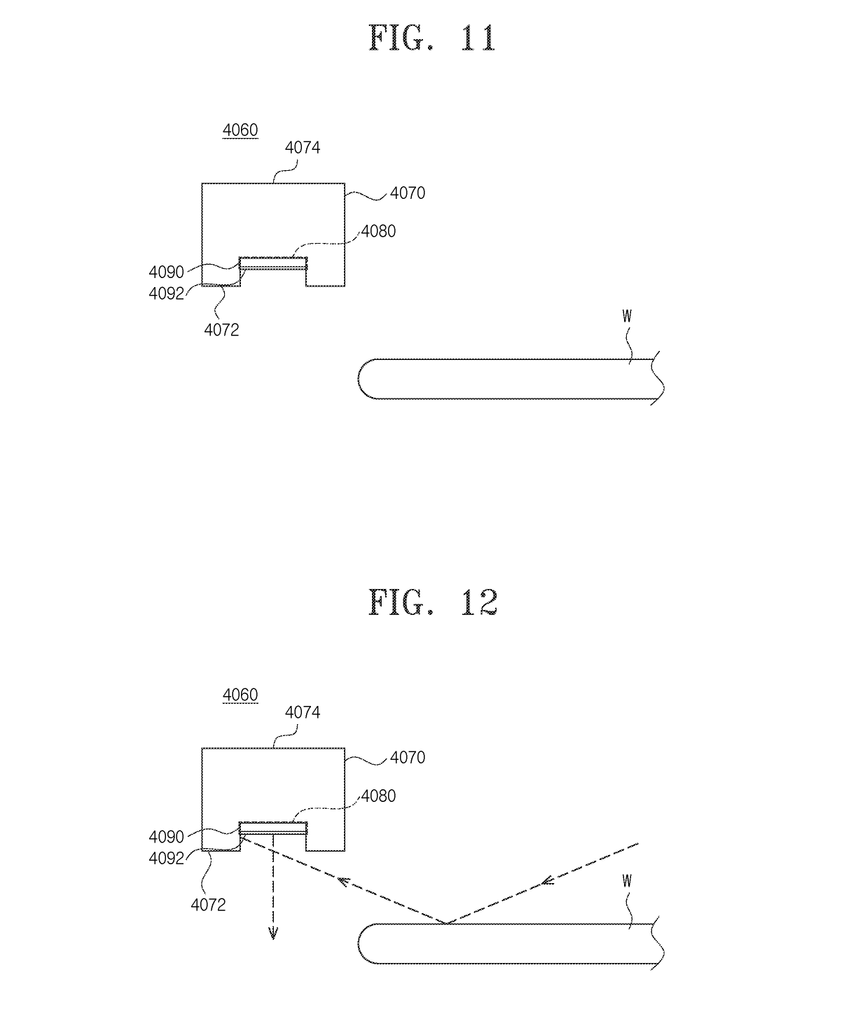

FIG. 12 is a diagram illustrating a light-receiving state of the light-receiving sensor when a substrate is in a regular position on the hand in the detector according to the transfer unit of FIG. 11.

First, when the groove 4076 is not provided, light emitted from a component, such as an illumination, of a transfer space or a part of light introduced into the transfer space is obliquely incident on the substrate W placed on the hand 3040. In this case, even though the substrate W is in the regular position on the hand 3040, the light-receiving sensor 4090 receives the light reflected from the substrate W, and thus it may be wrongly determined that the substrate W protrudes from the regular position on the hand 3040.

Referring to FIG. 12, when the groove 4076 is provided, light incident obliquely on the substrate W placed on the hand 3040 is reflected from the substrate W and directed toward the light-receiving sensor 4090. However, since the light-receiving sensor 4090 is inserted into the groove 4076, the light reflected from the substrate W does not reach the light-receiving sensor 4090.

FIG. 13 is a diagram schematically illustrating a third exemplary embodiment of the detector of the transfer unit. Hereinafter, differences between the transfer unit according to the first exemplary embodiment of FIG. 9 and the transfer unit according to the second exemplary embodiment of FIG. 11 will be mainly described.

Referring to FIG. 13, a transfer unit 3000 includes a base plate 3020, a hand 3040, and a detector 5060. In the transfer unit 3000 according to the exemplary embodiment of FIG. 13, the base plate 3020 and the hand 3040 are provided to be the same as or similar to the base plate 3020 and the hand 3040 of the transfer unit 3000 according to the exemplary embodiment of FIG. 9.

The detector 5060 includes a body 5070, a light-emitting sensor 5080, and a light-receiving sensor 5090. A groove 5076 is formed in the body 5070 on a bottom portion 5072 in a direction toward a top portion 5074. The groove 5076 is formed by an inner side wall 5076a and an inner upper wall 5076b.

The inner side wall 5076a is provided perpendicular to the bottom portion 5070 of the body 5072. The inner side wall 5076a is provided perpendicular to the bottom portion 5072 of the body 5070. The inner upper wall 5076b is obliquely provided so that the height thereof increases as the distance from the substrate W placed in the regular position on the hand increases.

A light-emitting sensor 5080 and a light-receiving sensor 5090 are installed in the body 5070. The light-receiving sensor 5090 is inserted into the groove 5076 formed in the body 5070. The light-receiving sensor 5090 is fixedly installed on the inner upper wall 5076b. In the light-receiving sensor 5090, a light-receiving surface 5092 that is a surface that receives light is installed parallel to the inner upper wall 5076b. That is, the light-receiving sensor 5090 is installed obliquely so that the height of the light-receiving surface 5092 increases as the light-receiving surface 5092 is away from the substrate W.

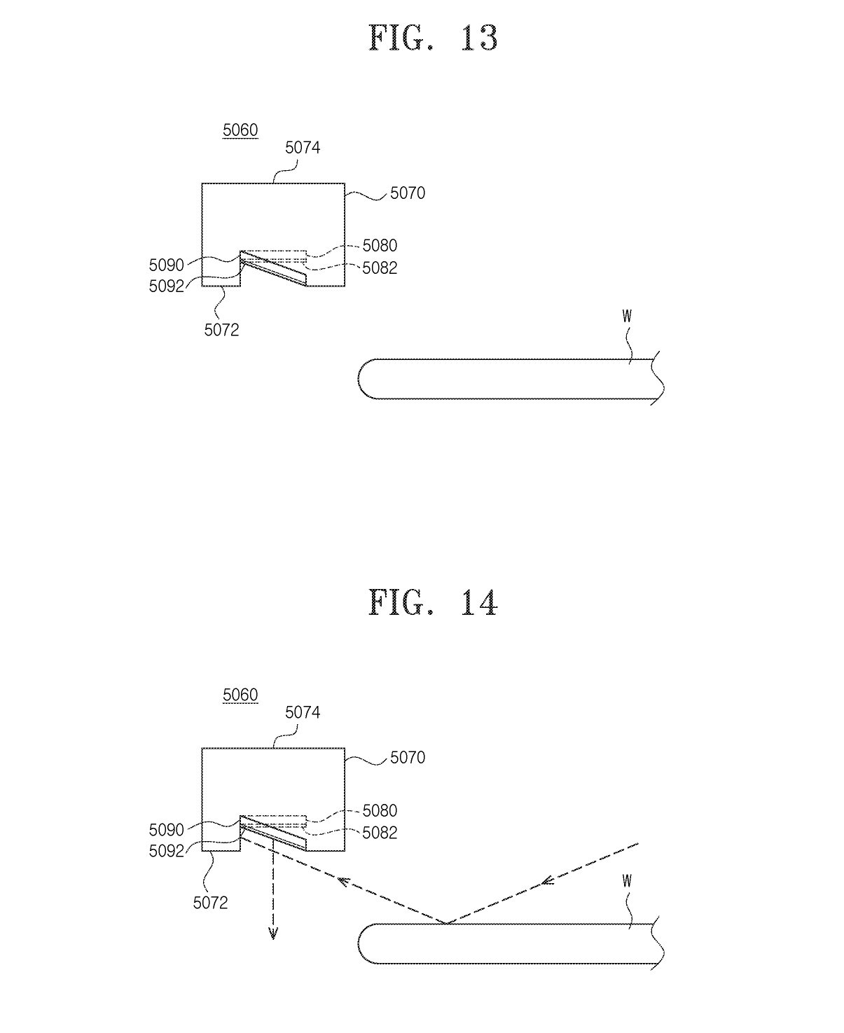

FIG. 14 is a diagram illustrating a light-receiving state of the light-receiving sensor when a substrate is in a regular position on the hand in the detector according to the transfer unit of FIG. 13.

First, when the light-receiving surface 5092 is not obliquely provided, light emitted from a component, such as an illumination, of a transfer space or a portion of light introduced into the transfer space is obliquely incident on the substrate W placed on the hand 3040. In this case, even though the substrate W is in the regular position on the hand 3040, the light-receiving sensor 5090 receives the light reflected from the substrate W, and thus it may be wrongly determined that the substrate W protrudes from the regular position on the hand 3040.

Referring to FIG. 14, when the light-receiving surface 5092 is obliquely provided, light obliquely incident on the substrate W placed on the hand is reflected from the substrate W and directed toward the light-receiving sensor 5090. However, since the light-receiving sensor 5090 is obliquely provided, light reflected from the substrate W does not reach the light-receiving sensor 5090.

Hereinafter, various modified examples of the transfer unit according to the present invention will be described. In the following exemplary embodiment, unless otherwise stated, a description will be made based on the first exemplary embodiment.

For example, in FIG. 9, the light blocking wall 4000 is provided on the bottom portion 3072 of the body, and the light-receiving surface 3092 of the light-receiving sensor 3090 is installed on the bottom portion 3072 of the body 3070. However, unlike this, as illustrated in FIG. 15, while the light blocking wall 4000 is provided on the bottom portion 3072 of the body, the light-receiving sensor 3090 may be installed to be inserted into the groove 4076 like the detector 4060 of the transfer unit 3000 of FIG. 11 according to the second exemplary embodiment described above.

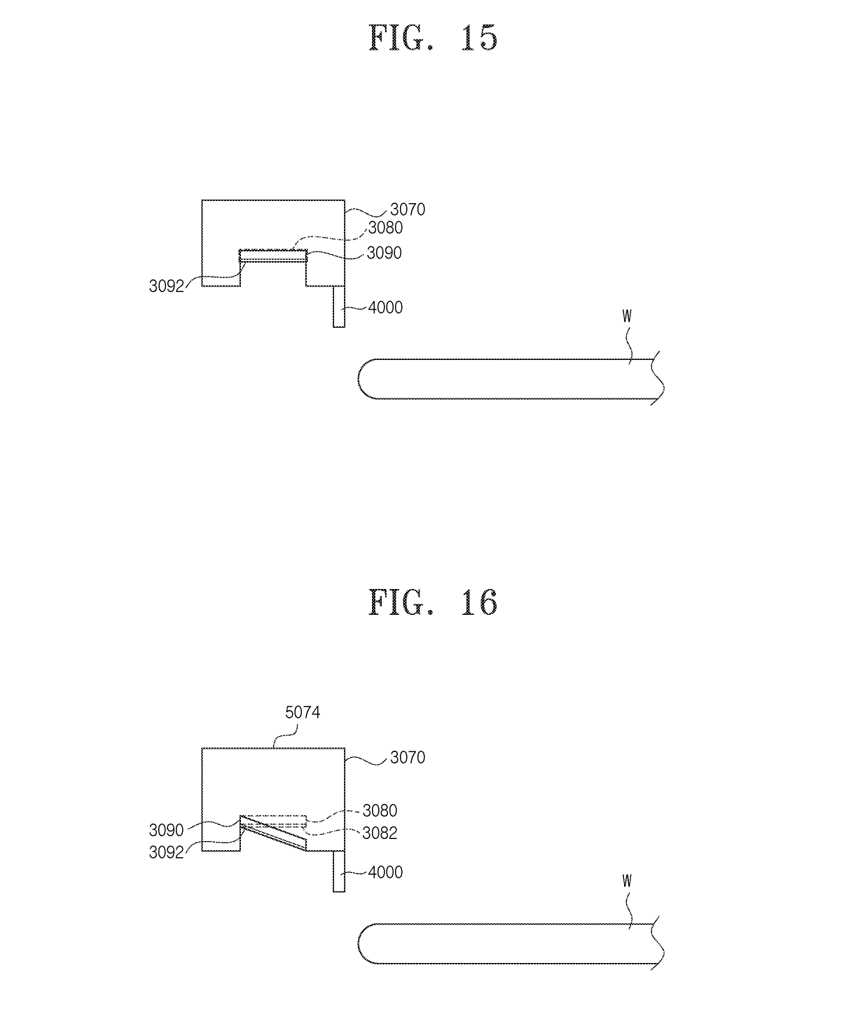

Optionally, as illustrated in FIG. 16, a light blocking wall 4000 is provided on the bottom surface 3072 of the body 3070, and the light-receiving surface 3092 of the light-receiving sensor 3090 may be obliquely installed in the groove 4076 as in the third exemplary embodiment of FIG. 15.

In the above exemplary embodiment, it has been described that the light-emitting sensor 3080 and the light-receiving sensor 3090 are both installed in the body 3070 of the detector 3060. On the contrary, as illustrated in FIG. 17, the light-emitting sensor 3080 may be installed at a position facing the light-receiving sensor in the vertical direction. In this case, when the substrate W does not protrude from the regular position on the hand, the light-receiving sensor receives light emitted from the light-emitting sensor.

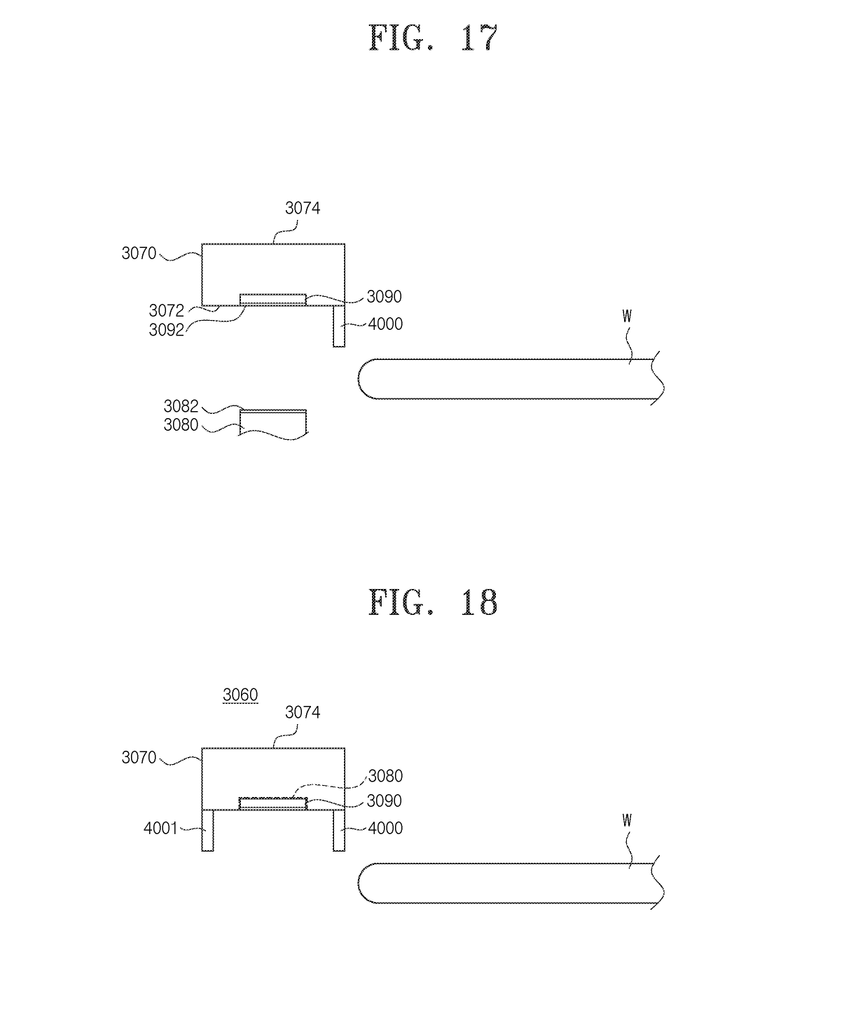

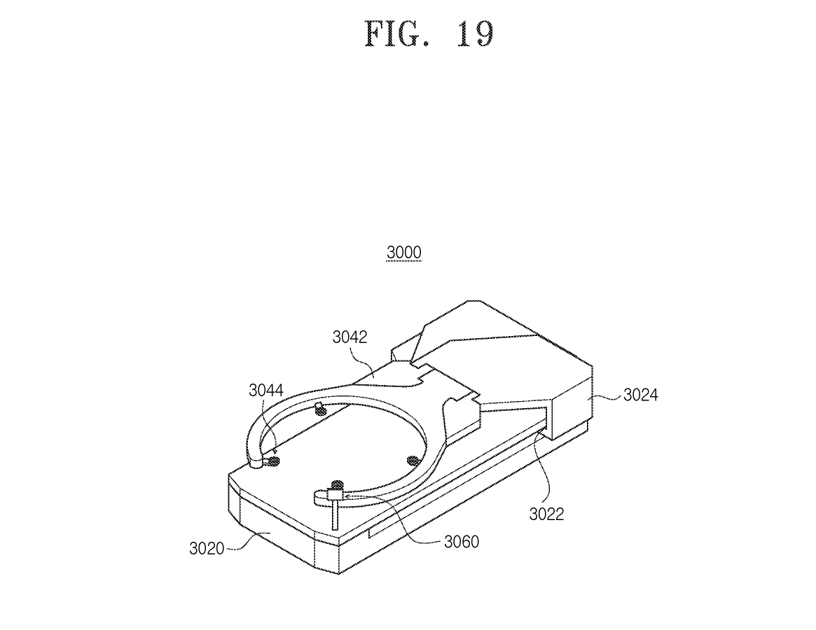

In the exemplary embodiment of FIG. 9, it has been described that the light blocking wall 4000 is installed between the substrate W positioned in the regular position and the light-receiving sensor 3090. However, this is illustrative and the present invention is not limited thereto. Unlike the above exemplary embodiment, as illustrated in FIG. 18, a light blocking wall 4001 may be installed in an area, other than the space between the substrate W which is positioned in the regular position and the light-receiving sensor 3090, in the bottom portion 3072 of the body 3070. Accordingly, light other than the light emitted from the light-emitting sensor 3080 in various directions other than the light reflected from the substrate W may be blocked from flowing into the light-receiving sensor 3090.

In the above exemplary embodiment, it has been described that the detector 3060 is fixedly coupled to the support installed in the hand 3040. However, this is illustrative and the present invention is not limited thereto, and as illustrated in FIG. 19, the detector 3060 may be supported by the base plate 3020. The detector may be provided to detect whether the substrate supported on the hand protrudes from the regular position on the hand when the hand is in the backward position.

In the above exemplary embodiment, it has been described as an example that the detectors 3060, 4060, and 5060 are provided to the transfer unit 3000 for transferring the substrate W in the substrate processing apparatus performing the application and development processes. However, the transfer unit, in which the above-described detectors 3060, 4060, and 5060 are installed, may be provided to the substrate processing apparatus performing processes other than those performing the application and development processes. For example, the transfer unit 3000, in which the above-described detectors 3060, 4060, and 5060 are installed, may be a transfer unit provided to an apparatus performing a process of cleaning the substrate W.

In the above-described example, it has been described that one hand 3040 is provided on the base plate 3020. However, unlike this, a plurality of hands 3040 that are independently driven may be disposed on the base plate 3020 to be spaced apart from each other in the vertical direction.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A transfer unit for transferring a substrate, the transfer unit comprising:
a hand on which a substrate is placed; and
a detector for detecting whether the substrate supported on the hand protrudes from a regular position on the hand,
wherein the detector includes:
a light-emitting sensor for emitting light;
a body in which a light-receiving sensor that receives light emitted from the light-emitting sensor is installed on a bottom surface thereof; and
a light blocking wall installed in the body and preventing light other than the light emitted by the light-emitting sensor from being introduced into the light-receiving sensor.

2. The transfer unit of claim 1, wherein the light blocking wall is provided to protrude downward from the body at a position between the substrate placed in the regular position on the hand and the light-receiving sensor.

3. The transfer unit of claim 1, wherein the light-emitting sensor and the body are installed on the hand.

4. The transfer unit of claim 1, wherein a groove is formed on a bottom portion of the body, and
the light-receiving sensor is disposed in the groove.

5. The transfer unit of claim 4, wherein a light-receiving surface of the light-receiving sensor is arranged upwardly inclined in a direction away from the substrate placed in the regular position on the hand.

6. The transfer unit of claim 4, wherein a light-receiving surface of the light-receiving sensor is provided parallel to the substrate placed in the regular position on the hand, and the light-receiving surface is located higher than the bottom portion of the body.

7. The transfer unit of claim 1, wherein the light-emitting sensor is installed in the body.

8. The transfer unit of claim 1, further comprising:
a base plate on which the hand is installed,
wherein the hand is provided so as to be movable forwardly and backwardly between a forward position and a backward position on the base plate, and
the detector is installed on the base plate to detect whether the substrate supported on the hand protrudes from the regular position on the hand in a state where the hand is placed in the backward position.

9. A transfer unit for transferring a substrate, the transfer unit comprising:
a hand on which a substrate is placed; and
a detector for detecting whether the substrate supported on the hand protrudes from a regular position on the hand,
wherein the detector includes:
a light-emitting sensor for emitting light; and
a body in which a light-receiving sensor that receives light emitted from the light-emitting sensor is installed,
a groove is formed on a bottom portion of the body, and
the light-receiving sensor is disposed in the groove.

10. The transfer unit of claim 9, wherein a light-receiving surface of the light-receiving sensor is arranged upwardly inclined in a direction away from the substrate placed in the regular position on the hand.

11. The transfer unit of claim 9, wherein a light-receiving surface of the light-receiving sensor is provided parallel to the substrate placed in the regular position on the hand, and
the light-receiving surface is located higher than the bottom portion of the body.

12. The transfer unit of claim 9, wherein the light-emitting sensor is installed in the body.

13. The transfer unit of claim 9, wherein the detector is installed on the hand.

14. The transfer unit of claim 13, further comprising:
a base plate on which the hand is installed,
wherein the hand is provided so as to movable forwardly and backwardly between a forward position and a backward position on the base plate, and
the detector is installed at an end of the hand to detect whether the substrate supported on the hand protrudes from the regular position when the hand is moved from the forward position to the backward position.

15. The transfer unit of claim 9, further comprising:
a base plate on which the hand is installed,
the hand is provided so as to be movable forwardly and backwardly between a forward position and a backward position on the base plate, and
the detector is installed on the base plate to detect whether the substrate supported on the hand protrudes from the regular position on the hand in a state where the hand is placed in the backward position.

16. A transfer unit for transferring a substrate, the transfer unit comprising:
a base plate;
a hand which is installed on the base plate so as to be movable forwardly and backwardly on the base plate, and on which the substrate is placed; and
a detector for detecting whether the substrate supported on the hand protrudes from a regular position on the hand,
wherein the detector includes:
a light-emitting sensor for emitting light;
a body in which a light-receiving sensor that receives light emitted from the light-emitting sensor is installed on a bottom surface thereof; and
a light blocking wall that is provided to protrude in a lower direction from the body at a position between the substrate placed in the regular position on the hand and the light-receiving sensor to prevent light other than the light emitted from the light-emitting sensor from being introduced into the light-receiving sensor.

17. The transfer unit of claim 16, wherein the detector is installed on the hand.

18. The transfer unit of claim 16, wherein the detector is installed on the base plate to detect whether the substrate supported on the hand protrudes from the regular position on the hand when the hand is placed in the backward position.

19. The transfer unit of claim 16, wherein a groove in which the light-receiving sensor is installed is formed on a bottom surface of the body, and
a light-receiving surface of the light-receiving sensor is arranged upwardly inclined in a direction away from the substrate placed in the regular position on the hand.

20. The transfer unit of claim 16, wherein a groove in which the light-receiving sensor is installed is formed on a bottom surface of the body, and
a light-receiving surface of the light-receiving sensor is provided parallel to the substrate placed in the regular position on the hand, and
the light-receiving surface is located higher than the bottom surface of the body.
